(19) United States
(12) Patent Application Publication
(10) Pub. No.: US 2025/0266658 A1
(43) Pub. Date: Aug. 21, 2025

(54) OPTICAL MODULATOR INTEGRATED LASER DEVICE, OPTICAL DEVICE, AND OPTICAL MODULATOR

(71) Applicant: SUMITOMO ELECTRIC DEVICE INNOVATIONS, INC., Yokohama-shi (JP)

(72) Inventor: Hiromitsu KAWAMURA, Yokohama-shi (JP)

(73) Assignee: SUMITOMO ELECTRIC DEVICE INNOVATIONS, INC., Yokohama-shi (JP)

(21) Appl. No.: 19/040,940

(22) Filed: Jan. 30, 2025

(30) Foreign Application Priority Data
Feb. 16, 2024 (JP) 2024-022273

(51) Int. Cl. H01S 5/026; H01S 5/02345; H01S 5/042

(52) U.S. Cl. CPC H01S 5/0265; H01S 5/02345; H01S 5/0264; H01S 5/04254; H01S 5/04256; H01S 5/0427

(57) ABSTRACT

An optical modulator integrated laser device comprising: a substrate; a laser unit provided on the substrate and configured to output laser light; an optical modulation unit provided on the substrate, including a modulation electrode supplied with one of modulation signals, and configured to modulate the laser light; a first signal pad provided on the substrate, configured to receive an input of the one of the modulation signals as a positive phase signal of a differential signal, and connected to the modulation electrode; a second signal pad provided on the substrate side by side with the first signal pad and configured to receive an input of another of the modulation signals as a negative phase signal of the differential signal; and a first terminating resistor provided on the substrate and including a first end connected to the first signal pad and a second end connected to the second signal pad.

### CROSS-REFERENCE TO RELATED APPLICATION

The present application is based upon and claims the benefit of the priority from Japanese patent application No. 2024-022273 filed on Feb. 16, 2024, the entire contents of which are incorporated herein by reference.

### TECHNICAL FIELD

The present disclosure relates to an optical modulator integrated laser device, an optical device, and an optical modulator.

### BACKGROUND

Japanese Unexamined Patent Publication No. 2001-308130 discloses techniques for a high-frequency circuit and a module and a communicator on which the high-frequency circuit is mounted. In the high-frequency circuit, a signal line for transmitting a high-frequency signal is connected to an element having capacitance by a first bonding wire. The element having capacitance is connected to a terminating resistor for impedance matching by a second bonding wire. In the high-frequency circuit, a magnitude of a characteristic impedance of a transmission line constituted by the first bonding wire, the second bonding wire, and the element having capacitance is larger than that of a characteristic impedance on an input side of the high-frequency signal. In the high-frequency circuit, a magnitude of inductance of the first bonding wire is smaller than that of inductance of the second bonding wire.

### SUMMARY

An optical modulator integrated laser device according to an embodiment of the present disclosure includes a substrate, a laser unit, an optical modulation unit, a first signal pad, a second signal pad, and a first terminating resistor. The laser unit is provided on the substrate and outputs laser light. The optical modulation unit is provided on the substrate, includes a modulation electrode supplied with one of modulation signals, and modulates the laser light. The first signal pad is provided on the substrate, receives an input of the one of the modulation signals as a positive phase signal of a differential signal, and is connected to the modulation electrode. The second signal pad is provided on the substrate side by side with the first signal pad and receives an input of another of the modulation signals as a negative phase signal of the differential signal. The first terminating resistor is provided on the substrate and includes a first end connected to the first signal pad and a second end connected to the second signal pad.

### BRIEF DESCRIPTION OF THE DRAWINGS

FIG. 1 is a plan view illustrating a transmission micro optical device which is an optical device according to a first embodiment of the present disclosure.

FIG. 2 is a circuit diagram of the transmission micro optical device.

FIG. 3 is a perspective view illustrating enlargement of a part of the transmission micro optical device.

FIG. 4 is a plan view illustrating enlargement of a part of the transmission micro optical device.

FIG. 5 is a sectional view taken along line V-V in FIG. 4.

FIG. 6 is a sectional view illustrating some steps for manufacturing an optical modulator integrated semiconductor laser.

FIG. 7 is a sectional view illustrating some steps for manufacturing an optical modulator integrated semiconductor laser.

FIG. 8 is a perspective view illustrating enlargement of a part of a transmission micro optical device according to a first modified example.

FIG. 9 is a plan view illustrating enlargement of a part of the transmission micro optical device according to the first modified example.

FIG. 10 is a perspective view illustrating enlargement of a part of a transmission micro optical device according to a second modified example.

FIG. 11 is a plan view illustrating enlargement of a part of the transmission micro optical device according to the second modified example.

FIG. 12 is a plan view illustrating enlargement of a part of the transmission micro optical device according to the second modified example.

FIGS. 13A and 13B are circuit diagrams illustrating simplification of a circuit according to the first embodiment and a circuit according to the second modified example.

FIG. 14 is a plan view illustrating a transmission micro optical device according to a comparative example.

FIG. 15 is a circuit diagram of the transmission micro optical device.

FIG. 16 is a plan view illustrating partial enlargement of the transmission micro optical device.

### DETAILED DESCRIPTION

With an increase in speed and capacity of optical communication, there is need for an increase in frequency bandwidth of an optical modulator of an optical device. However, when a modulation signal has a high frequency such as 100 GHz or higher, electrical reflection of the modulation signal is likely to increase. As reflection of the modulation signal increases, a loss of the modulation signal increases. Accordingly, for example, the modulation signal may not be likely to be satisfactorily transmitted to the optical modulator.

An objective of the present disclosure is to provide an optical modulator integrated laser device, an optical device, and an optical modulator that can decrease a loss of a modulation signal due to reflection.

### Embodiments of Present Disclosure

Details of embodiments of the present disclosure will be first mentioned below.
[1] An optical modulator integrated laser device according to an embodiment of the present disclosure includes a substrate, a laser unit, an optical modulation unit, a first signal pad, a second signal pad, and a first terminating resistor. The laser unit is provided on the substrate and outputs laser light. The optical modulation unit is provided on the substrate, includes a modulation electrode supplied with one of modulation signals, and modulates the laser light. The first signal pad is provided on the substrate, receives an input of the one of the modulation signals as a positive phase signal of a differential signal, and is connected to the modulation electrode. The second signal pad is provided on the substrate side by side with the first signal pad and receives an input of another of the modulation signals as a negative phase signal of the differential signal. The first terminating resistor is provided on the substrate and includes a first end connected to the first signal pad and a second end connected to the second signal pad.

In the optical modulator integrated laser device according to [1], a wire (hereinafter referred to as a first wire) connected to the first signal pad and a wire (hereinafter referred to as a second wire) connected to the second signal pad are provided side by side. Since the first wire inputs one of the modulation signals and the second wire inputs the other of the modulation signals of a phase opposite to that of the one of the modulation signals, a virtual reference potential line appears between the first wire and the second wire. Accordingly, mismatching in input impedance of the modulation signal in the first wire is reduced. The modulation electrode, the first signal pad, and the first terminating resistor are provided on the same substrate. Accordingly, it is possible to much shorten the distance of the conductive path between the modulation electrode and the first end of the first terminating resistor. As a result, it is possible to reduce electrical reflection of one of the modulation signals at the first end of the first terminating resistor. Accordingly, it is possible to reduce a loss of the modulation signal due to reflection.
[2] In the optical modulator integrated laser device according to [1], a distance of a conductive path between a connection point of the first signal pad to which a first wire for inputting the one of the modulation signals is connected and the first end of the first terminating resistor may be less than ¼ of a wavelength of the modulation signals.
[3] In the optical modulator integrated laser device according to [2], a distance of a conductive path between the connection point and the modulation electrode may be less than ¼ of the wavelength of the modulation signals.
[4] The optical modulator integrated laser device according to any one of [1] to [3] may further include: a third signal pad provided on the substrate on a side opposite to the second signal pad with respect to the first signal pad; a fourth signal pad provided on the substrate on a side opposite to the first signal pad with respect to the second signal pad; a second terminating resistor provided on the substrate and including a first end connected to the first signal pad and a second end connected to the third signal pad; and a third terminating resistor provided on the substrate and including a first end connected to the second signal pad and a second end connected to the fourth signal pad.
[5] In the optical modulator integrated laser device according to [4], a distance of a conductive path between a connection point of the first signal pad to which a first wire for inputting the one of the modulation signals is connected and the first end of the second terminating resistor may be less than ¼ of a wavelength of the modulation signals.
[6] In the optical modulator integrated laser device according to [4] or [5], a distance of a conductive path between a connection point of the second signal pad to which a second wire for inputting another of the modulation signals is connected and the first end of the third terminating resistor may be less than ¼ of a wavelength of the modulation signals.
[7] In the optical modulator integrated laser device according to any one of [4] to [6], a distance of a conductive path between a connection point of the third signal pad to which a third wire with a ground potential is connected and the second end of the second terminating resistor may be less than ¼ of a wavelength of the modulation signals.
[8] In the optical modulator integrated laser device according to any one of [4] to [7], a distance of a conductive path between a connection point of the fourth signal pad to which a fourth wire with a ground potential is connected and the second end of the third terminating resistor may be less than ¼ of a wavelength of the modulation signals.
[9] An optical modulator integrated laser device according to another embodiment of the present disclosure includes: a substrate; a laser unit provided on the substrate and configured to output laser light; an optical modulation unit provided on the substrate, including a modulation electrode supplied with one of modulation signals, and configured to modulate the laser light; a first signal pad provided on the substrate, configured to receive an input of the one of the modulation signals as a positive phase signal of a differential signal, and connected to the modulation electrode; a second signal pad provided on the substrate side by side with the first signal pad and configured to receive an input of another of the modulation signals as a negative phase signal of the differential signal; and a first terminating resistor provided on the substrate and including a first end connected to the modulation electrode and a second end connected to the second signal pad.
[10] The optical modulator integrated laser device according to [9] may further include a line connecting the second end of the first terminating resistor to the second signal pad. The line may be provided on a side opposite to the first signal pad with respect to the second signal pad and extend along the modulation electrode.
[11] An optical device according to another embodiment of the present disclosure includes: the optical modulator integrated laser device according to any one of [1] to [3]; a carrier in which a first transmission line and a second transmission line are provided on a top surface and in which the optical modulator integrated laser device is mounted; a first wire connecting the first signal pad to the first transmission line; and a second wire connecting the second signal pad to the second transmission line.
[12] In the optical device according to [11], a distance of a conductive path between a connection point of the first signal pad to which the first wire for inputting the one of the modulation signals is connected and the first end of the first terminating resistor may be less than ¼ of a wavelength of the modulation signals.
[13] In the optical device according to [12], a distance of a conductive path between the connection point and the modulation electrode may be less than ¼ of the wavelength of the modulation signals.
[14] An optical modulator according to another embodiment of the present disclosure includes: a substrate; an optical modulation unit provided on the substrate, including a modulation electrode supplied with one of modulation signals, and configured to modulate laser light; a first signal pad provided on the substrate, configured to receive an input of the one of the modulation signals as a positive phase signal of a differential signal, and connected to the modulation electrode; a second signal pad provided on the substrate side by side with the first signal pad and configured to receive an input of another of the modulation signals as a negative phase signal of the differential signal; and a first terminating resistor provided on the substrate and including a first end connected to the first signal pad and a second end connected to the second signal pad.
[15] In the optical modulator according to [14], a distance of a conductive path between a connection point of the first signal pad to which a first wire for inputting the one of the modulation signals is connected and the first end of the first terminating resistor may be less than ¼ of a wavelength of the modulation signals.
[16] In the optical modulator according to [15], a distance of a conductive path between the connection point and the modulation electrode may be less than ¼ of the wavelength of the modulation signals.
[17] The optical modulator according to any one of to may further include a laser unit provided on the substrate and configured to output the laser light.

### Details of Embodiments of Present Disclosure

Specific examples of an optical modulator integrated laser device, an optical device, and an optical modulator according to the present disclosure will be described below with reference to the accompanying drawings. The present disclosure is not limited to such examples, is defined by the appended claims, and is intended to include all modifications within meanings and scopes equivalent to the claims. In the following description, the same elements in the drawings will be referred to by the same reference signs, and repeated description thereof will be omitted. In the following description, a reference potential may be referred to as a ground potential.

### First Embodiment

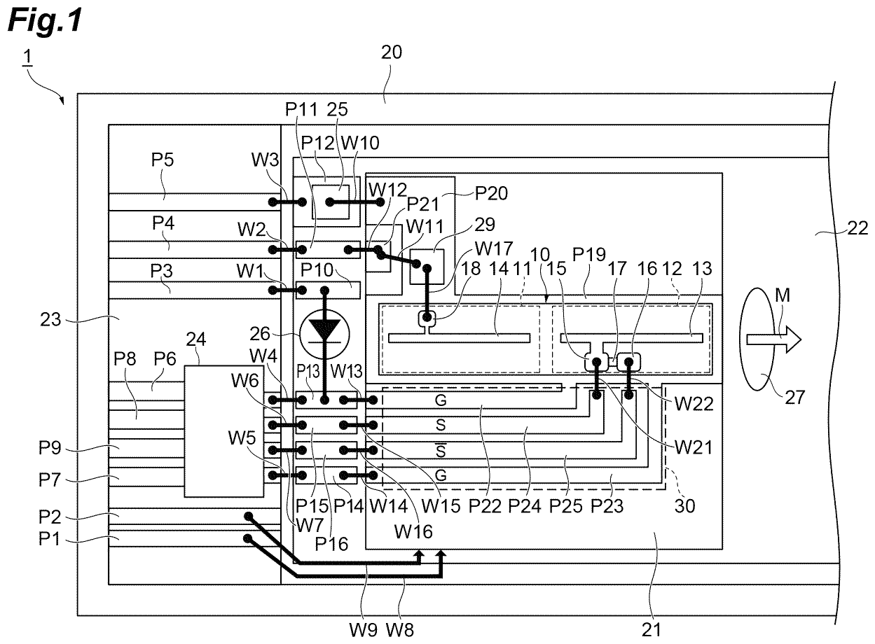

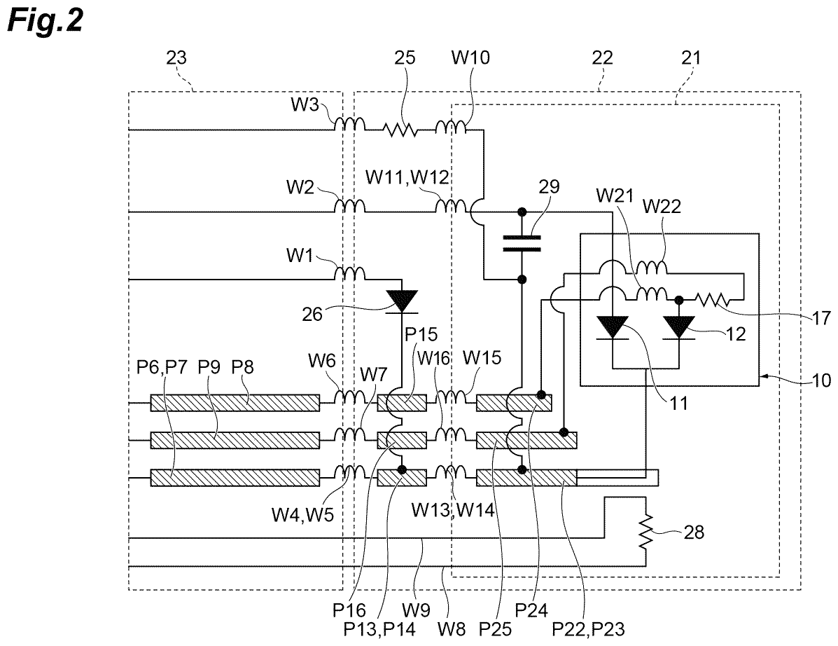

FIG. 1 is a plan view illustrating a transmission micro optical device 1 which is an optical device according to a first embodiment of the present disclosure. FIG. 2 is a circuit diagram of the transmission micro optical device 1. A configuration of the transmission micro optical device 1 will be described below with reference to FIGS. 1 and 2.

As illustrated in FIG. 1, the transmission micro optical device 1 includes a package 20, a substrate 21 (a chip-on-carrier), a substrate 22 (a mount carrier), and a substrate 23. The package 20 accommodates the substrate 21, the substrate 22, and the substrate 23. The substrate 22 is disposed side by side with the substrate 23. The substrate 21 is disposed on the substrate 22. A material of the substrate 21 and the substrate 22 is, for example, an insulator such as ceramic.

The transmission micro optical device 1 further includes wiring patterns P1, P2, P3, P4, and P5, ground potential lines P6 and P7, signal lines P8 and P9, and a differential driver IC 24 (a differential drive circuit) which are provided on the substrate 23. The wiring patterns P1, P2, P3, P4, and P5, the ground potential lines P6 and P7, and the signal lines P8 and P9 extend from one side wall of the package 20 toward the substrate 22 and are connected to an external circuit outside of the transmission micro optical device 1 via terminals which are not illustrated. The signal line P8 allows one of high-frequency modulation signals (hereinafter referred to as a positive phase signal) which is input from the outside of the transmission micro optical device 1 to propagate therein. The signal line P9 allows the other of the modulation signals (hereinafter referred to as a negative phase signal) which has a phase opposite to the one of the modulation signals, the negative phase signal is input from the outside of the transmission micro optical device 1 to propagate therein. That is, the positive phase signal propagating in the signal line P8 and the negative phase signal propagating in the signal line P9 form a differential signal. The ground potential lines P6 and P7 have a ground potential (a reference potential) which is input from a circuit on the outside of the transmission micro optical device 1. The signal lines P8 and P9 and the ground potential lines P6 and P7 constitute a transmission line.

Four input terminals of the differential driver IC 24 are connected to the ground potential lines P6 and P7 and the signal lines P8 and P9, respectively. The differential driver IC 24 amplifies the differential signal propagating in the signal lines P8 and P9 and outputs the amplified differential signal (the positive phase signal and the negative phase signal).

The transmission micro optical device 1 further includes wiring patterns P10, P11, and P12, ground potential lines P13 and P14, signal lines P15 and P16, a thermistor 25, a monitoring photodiode 26, and a lens 27 which are provided on the substrate 22.

The wiring pattern P10 is connected to the wiring pattern P3 by a wire W1. The wiring pattern P11 is connected to the wiring pattern P4 by a wire W2. The wiring pattern P12 is connected to the wiring pattern P5 by a wire W3. The ground potential line P13 is connected to one output terminal with the reference potential out of four output terminals of the differential driver IC 24 by a wire W4. The ground potential line P14 is connected to another output terminal with the reference potential out of the four output terminals of the differential driver IC 24 by a wire W5. The signal line P15 is connected to an output terminal for outputting a positive phase signal out of the four output terminals of the differential driver IC 24 by a wire W6. The signal line P16 is connected to an output terminal for outputting a negative phase signal out of the four output terminals of the differential driver IC 24 by a wire W7.

The thermistor 25 is provided on the wiring pattern P12. The thermistor 25 shows a resistance value corresponding to the temperature. This resistance value is output via the wiring pattern P12, the wire W3, and the wiring pattern P5 and is detected by an external circuit outside of the transmission micro optical device 1.

The monitoring photodiode 26 is connected between the wiring pattern P10 and the ground potential line P13. In order to make an average intensity of emission light M constant, the monitoring photodiode 26 detects backlight which is emitted from an optical modulator integrated semiconductor laser 10 (which will be described later). The monitoring photodiode 26 outputs an electrical signal corresponding to the intensity of the backlight to an external circuit outside of the transmission micro optical device 1 via the wiring pattern P10, the wire W1, and the wiring pattern P3. The lens 27 is optically coupled to a light emitting end of an optical modulator integrated semiconductor laser 10 and collimates the emission light M which is emitted from the optical modulator integrated semiconductor laser 10.

A temperature control element (thermoelectric cooler (TEC)) 28 (which is illustrated in only FIG. 2) is provided on the rear of the substrate 22. One electrode of the TEC 28 is connected to the wiring pattern P1 by a wire W8. The other electrode of the TEC 28 is connected to the wiring pattern P2 by a wire W9. Electric power for driving the TEC 28 is input from a circuit outside of the transmission micro optical device 1 via the wiring pattern P1 and the wiring pattern P2. The circuit outside of the transmission micro optical device 1 controls a magnitude of electric power for driving the TEC 28 on the basis of the ambient temperature (that is, the resistance value of the thermistor 25) of the optical modulator integrated semiconductor laser 10. Accordingly, the temperature of the optical modulator integrated semiconductor laser 10 is maintained at a predetermined temperature, and the wavelength of the emission light M is maintained at a predetermined wavelength.

A ground potential line P20, a wiring pattern P21, and a bypass capacitor 29 are provided on the substrate 21. The ground potential line P20 is connected to the ground terminal of the thermistor 25 by a wire W10. The ground potential line P20 is connected to a ground pattern P19 (which will be described later). The ground potential line P20 has the ground potential (the reference potential).

The bypass capacitor 29 is provided on the ground potential line P20. A lower electrode of the bypass capacitor 29 is connected to the ground potential line P20. An upper electrode of the bypass capacitor 29 is connected to the wiring pattern P21 by a wire W11. The wiring pattern P21 is connected to the wiring pattern P11 by a wire W12.

The transmission micro optical device 1 includes an optical modulator integrated semiconductor laser 10, a ground pattern P19, and a transmission line 30. The ground pattern P19 is a metal film provided on the substrate 21. The ground pattern P19 has the ground potential (the reference potential).

The transmission line 30 includes a ground potential line P22, a ground potential line P23, a signal line P24 (a first transmission line), and a signal line P25 (a second transmission line). The signal line P24 and the signal line P25 are metal films which are provided side by side with each other in a direction crossing an extending direction thereof. The ground potential line P22 and the ground potential line P23 are metal films which are provided at positions at which the signal line P24 and the signal line P25 are interposed therebetween. The ground potential line P22 extends along the signal line P24, and the ground potential line P23 extends along the signal line P25. As illustrated in FIG. 1, a first end of the ground potential line P22 is connected to the ground potential line P13 by a wire W13. A first end of the ground potential line P23 is connected to the ground potential line P14 by a wire W14. Second ends of the ground potential line P22 and the ground potential line P23 are connected to the ground pattern P19. A first end of the signal line P24 is connected to the signal line P15 by a wire W15. A first end of the signal line P25 is connected to the signal line P16 by a wire W16. A positive phase signal from the differential driver IC 24 is transmitted from the signal line P24 to a signal pad 15 via a wire W21. A negative phase signal from the differential driver IC 24 is transmitted to a signal pad 16 via a wire W22.

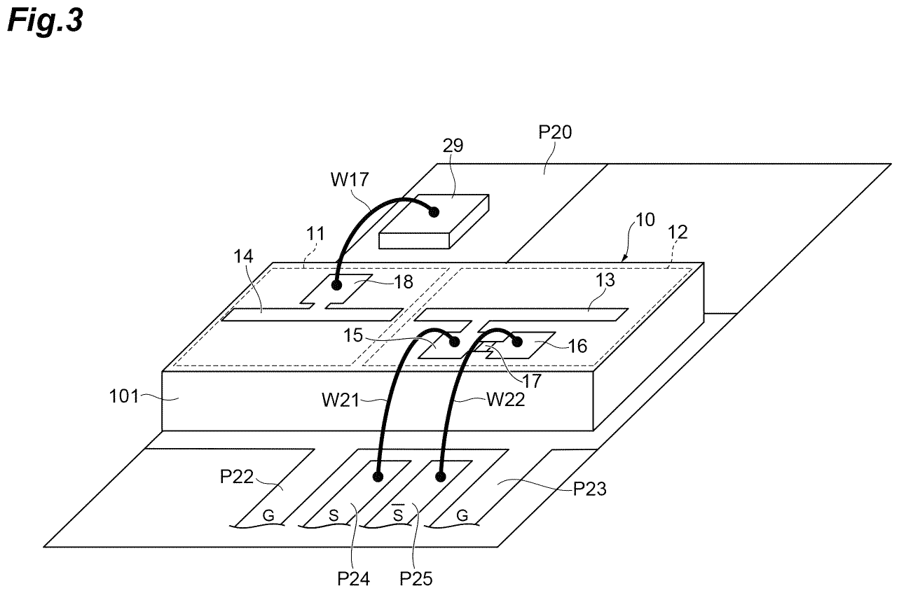

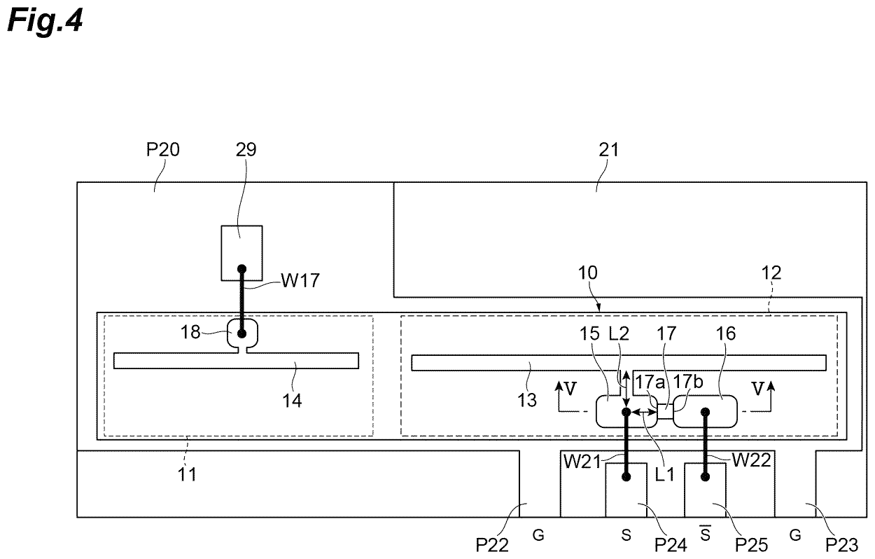

The optical modulator integrated semiconductor laser 10 according to the present embodiment is an example of the optical modulator integrated laser device according to the present disclosure. The optical modulator integrated semiconductor laser 10 is provided on the ground pattern P19. FIG. 3 is a perspective view illustrating enlargement of a part of the transmission micro optical device 1. FIG. 4 is a plan view illustrating enlargement of a part of the transmission micro optical device 1. As illustrated in FIGS. 3 and 4, the optical modulator integrated semiconductor laser 10 includes a substrate 101, a laser unit 11, an optical modulation unit 12, a terminating resistive film 17 (a first terminating resistor), a wire W21 (a first wire), and a wire W22 (a second wire). The substrate 101 has a rectangular parallelepiped shape. The laser unit 11 is disposed in an area which is closer to the substrate 23 than the optical modulation unit 12 on the substrate 101. As illustrated in FIG. 1, the laser unit 11 is interposed between the transmission line 30 and the ground potential line P20. The laser unit 11 includes an active area and generates laser light with a light intensity which is temporally constant by supplying a current to the active area. The laser unit 11 includes a drive electrode 14 and a pad 18 on the surface thereof. The drive electrode 14 extends in a laser resonance direction (an arrangement direction of the laser unit 11 and the optical modulation unit 12) and supplies a current to the active area. The pad 18 is arranged side by side with the drive electrode 14 in a direction crossing an extending direction of the drive electrode 14 and is connected to the drive electrode 14. The pad 18 is connected to the upper electrode of the bypass capacitor 29 by a wire W17. Accordingly, a drive current is supplied from the outside of the transmission micro optical device 1 to the drive electrode 14 via the wiring pattern P4, the wiring pattern P11, the wiring pattern P21, the upper electrode of the bypass capacitor 29, and the pad 18.

The optical modulation unit 12 is provided closer to the lens 27 than the laser unit 11. The optical modulation unit 12 includes a light absorbing layer, allows the light absorbing layer to modulate laser light output from the laser unit 11, and outputs the modulated emission light M. The backlight is laser light which is output from the laser unit 11 without passing through the optical modulation unit 12. The laser unit 11 and the optical modulation unit 12 are monolithically formed on the substrate 101. The optical modulation unit 12 includes a modulation electrode 13, a signal pad 15 (a first signal pad), and a signal pad 16 (a second signal pad). The optical modulation unit 12 modulates the laser light by transmitting or cutting off the laser light with supply of a current to the light absorbing layer. The modulation electrode 13 supplies a modulation current (a modulation signal) to the light absorbing layer. Accordingly, the laser light is transmitted or cut off by the light absorbing layer on the basis of the input modulation signal. The modulation electrode 13 extends in the same direction as a propagation direction of laser light in a plan view. On the top surface of the optical modulator integrated semiconductor laser 10, the modulation electrode 13 is provided substantially at the center in a direction perpendicular to the propagation direction of laser light.

The signal pad 15 and the signal pad 16 are provided closer to the transmission line 30 than the modulation electrode 13. The signal pad 15 is connected to a first end of the wire W21 connected to the modulation electrode 13 to input a positive phase signal to the optical modulation unit 12. The signal pad 16 is provided side by side with the signal pad 15 in a length direction of the modulation electrode 13. The signal pad 16 is connected to a first end of the wire W22 for inputting a negative phase signal to the optical modulation unit 12. The signal pad 15 is provided closer to the laser unit 11 than the signal pad 16. The signal pad 15 and the signal pad 16 have a film shape and has a substantially rectangular shape in a plan view. The material of the signal pad 15 and the signal pad 16 is metal and is, for example, gold (Au). The thickness of the signal pad 15 and the signal pad 16 are, for example, equal to or greater than 3 μm and equal to or less than 10 μm.

A second end of the wire W21 is connected to a second end of the signal line P24 of the transmission line 30. A second end of the wire W22 is connected to a second end of the signal line P25 of the transmission line 30. When seen in the thickness direction of the substrate 101, the extending direction of the wire W21 and the wire W22 crosses the extending direction of the modulation electrode 13. The wire W21 and the wire W22 are arranged side by side in the extending direction of the modulation electrode 13. For example, when seen in the thickness direction of the substrate 101, the wire W21 and the wire W22 are parallel with each other. The wire W21 and the wire W22 are, for example, bonding wires formed of Au. A diameter of a cross-section of the wire W21 and the wire W22 is, for example, 25 μm. A gap between the wire W21 and the wire W22 is, for example, several tens of μm. A difference between the length of the wire W21 and the length of the wire W22 is less than ¼, less than ⅛, less than 1/10, or less than 1/12 of a wavelength of a modulation signal.

The terminating resistive film 17 is provided between the signal pad 15 and the signal pad 16. The terminating resistive film 17 reduces reflection of a modulation signal. A first end 17a (see FIG. 4) of the terminating resistive film 17 is connected to the signal pad 15. A second end 17b (see FIG. 4) of the terminating resistive film 17 is connected to the signal pad 16. A distance of a conductive path (an electrical length) L1 between a connection point between the wire W21 and the signal pad 15 and the first end 17a of the terminating resistive film 17 is, for example, less than ¼, less than ⅛, less than 1/10, or less than 1/12 of a wavelength of a modulation signal. The distance L1 is, for example, equal to or greater than 1/1000 of the wavelength of the modulation signal. Similarly, a distance of a conductive path (an electrical length) L2 between a connection point between the wire W21 and the signal pad 15 and the modulation electrode 13 is, for example, less than ¼, less than ⅛, less than 1/10, or less than 1/12 of the wavelength of the modulation signal. The distance L2 is, for example, equal to or greater than 1/1000 of the wavelength of the modulation signal. Specifically, when the wavelength of the modulation signal is, for example, 1200 μm, the distance L1 and the distance L2 are less than 300 μm, less than 150 μm, less than 120 μm, or less than 100 μm and equal to or greater than 1 μm.

The terminating resistive film 17 has a rectangular shape. The material of the terminating resistive film 17 is, for example, a metal such as nickel chromium (NiCr), titanium tungsten (TiW), tantalum nitride (TaN), or platinum (Pt). The thickness of the terminating resistive film 17 is, for example, equal to or greater than 100 nm and equal to or less than 300 nm. The terminating resistive film 17 is formed of a resistive pattern of a thin film which is formed by vapor deposition and lifting-off thereafter, sputtering, or the like. By setting the resistance value of the terminating resistive film 17 to, for example, 100Ω, a value of terminating impedance is 50Ω. The value of terminating impedance is generally often 50Ω or may be different from 50Ω by addition of a capacitor, an inductor, or the like or adjustment of a resistance value.

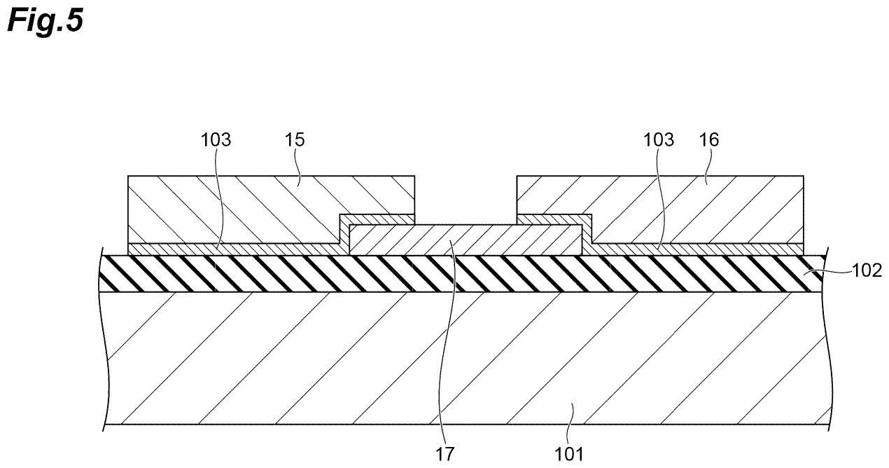

FIG. 5 is a sectional view taken along line V-V in FIG. 4. The optical modulation unit 12 includes a passivation film 102 and a seed layer 103 on the substrate 101. The substrate 101 is provided on the ground pattern P19 in contact with the ground pattern P19. The substrate 101 is formed of, for example, semi-insulating InP or n-type InP, or an insulator. The passivation film 102 is provided on the substrate 101. The material of the passivation film 102 is, for example, an insulator such as SiO₂ or SiN. The thickness of the passivation film 102 is, for example, equal to or greater than 300 nm and equal to or less than 500 nm. The terminating resistive film 17 is provided on the passivation film 102. The signal pad 15 and the signal pad 16 are provided on the passivation film 102 and include a part provided on the terminating resistive film 17 and a part provided in an area of the passivation film 102 without the terminating resistive film 17. The seed layer 103 is provided between the passivation film 102 and both the signal pad 15 and the signal pad 16 and between the terminating resistive film 17 and both the signal pad 15 and the signal pad 16. The material of the seed layer 103 is, for example, gold (Au). The thickness of the seed layer 103 is, for example, equal to or greater than 100 nm and equal to or less than 200 nm. The signal pad 15 and the signal pad 16 are not in contact with each other, and the terminating resistive film 17 includes parts exposed from the signal pad 15 and the signal pad 16.

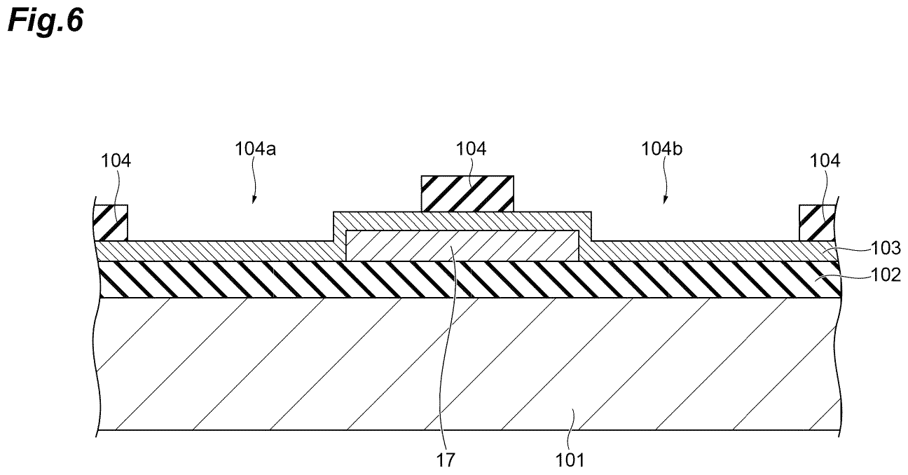

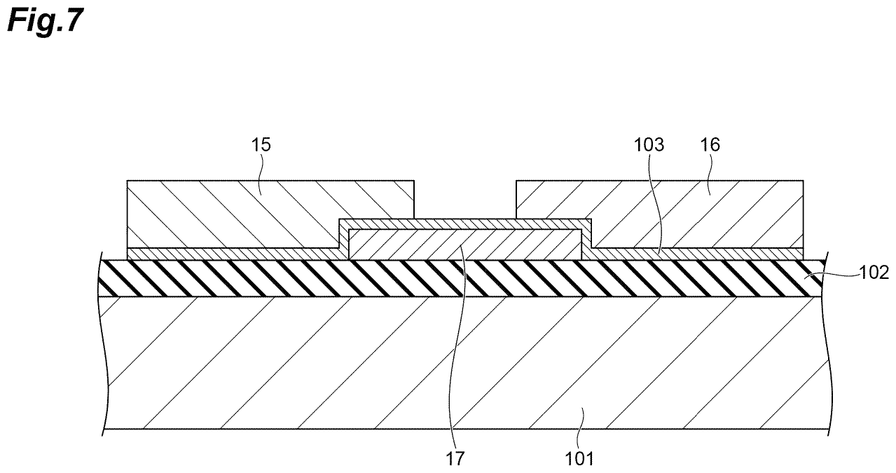

FIGS. 6 and 7 are sectional views illustrating some steps of a process of manufacturing the optical modulator integrated semiconductor laser 10. Some steps of the process of manufacturing the optical modulator integrated semiconductor laser 10 will be described below. In the optical modulation unit 12, first, the substrate 101 is prepared. Then, the passivation film 102 is formed on the substrate 101. Thereafter, a resist mask which is not illustrated is formed on the surface of the passivation film 102 through photolithography and the terminating resistive film 17 is formed on the passivation film 102. Then, the seed layer 103 is formed on the surfaces of the terminating resistive film 17 and the passivation film 102. Thereafter, a resist mask 104 in which an opening 104a and an opening 104b are provided is formed on the surface of the seed layer 103 through photolithography. Subsequently, by performing gold plating on the opening 104a and the opening 104b, the signal pad 15 is formed in the opening 104a and the signal pad 16 is formed in the opening 104b as illustrated in FIG. 7. Finally, the resist mask 104 is removed from the optical modulation unit 12, and the exposed parts of the seed layer 103 are removed using the signal pad 15 and the signal pad 16 as a mask. Accordingly, the signal pad 15, the terminating resistive film 17, and the signal pad 16 illustrated in FIG. 5 are formed.

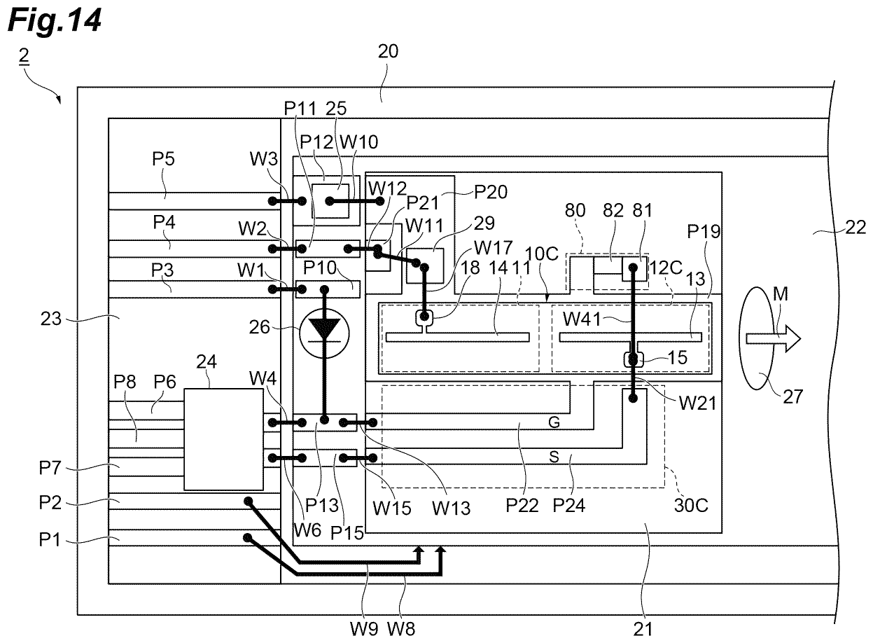

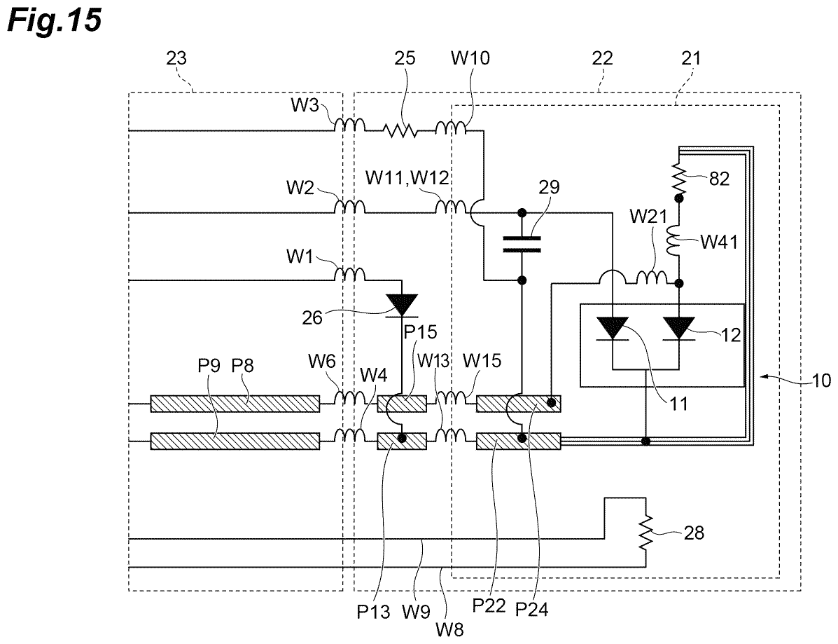

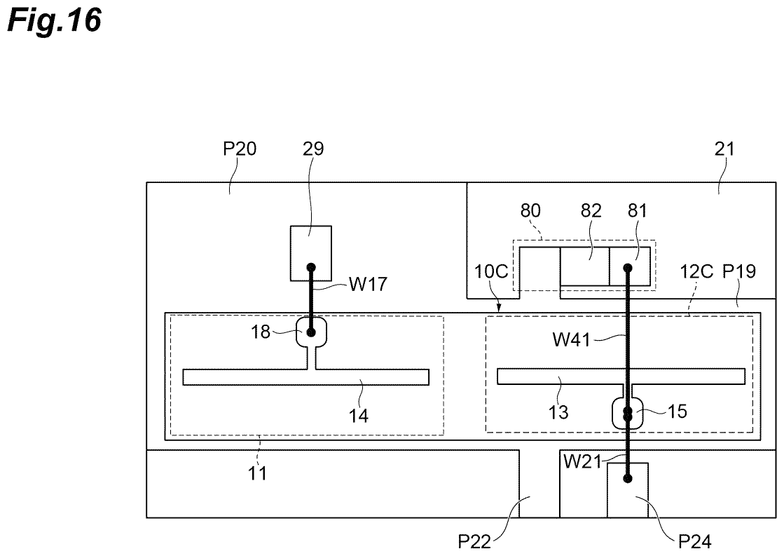

Advantages which are obtained by the transmission micro optical device 1 and the optical modulator integrated semiconductor laser 10 having the aforementioned configuration will be described below in comparison with a comparative example. FIG. 14 is a plan view illustrating a transmission micro optical device 2 according to a comparative example. FIG. 15 is a circuit diagram of the transmission micro optical device 2. FIG. 16 is a plan view illustrating enlargement of a part of the transmission micro optical device 2. The transmission micro optical device 2 is different from the transmission micro optical device 1 mainly in the following points. The transmission micro optical device 2 includes an optical modulator integrated semiconductor laser 10C and a transmission line 30C instead of the optical modulator integrated semiconductor laser 10 and the transmission line 30. The transmission micro optical device 2 includes a terminating portion 80.

The optical modulator integrated semiconductor laser 10C includes an optical modulation unit 12C instead of the optical modulation unit 12. The optical modulation unit 12C is different from the optical modulation unit 12 in that the signal pad 16 and the wire W22 are not provided and a first end of a wire W41 is connected to the signal pad 15. The terminating resistive film 17 is not provided on the substrate. The transmission line 30C is different from the transmission line 30 in that the ground potential line P23 and the signal line P25 are not provided. The terminating portion 80 is provided on a side opposite to the transmission line 30C with respect to the optical modulator integrated semiconductor laser 10C on the substrate 21. The terminating portion 80 includes a protruding portion from the ground pattern P19, a pad 81, and a terminating resistive film 82. A second end of the wire W41 is connected to the pad 81. The terminating resistive film 82 includes a first end connected to the protruding portion from the ground pattern P19 and a second end connected to the pad 81.

In the transmission micro optical device 2, since the terminating resistive film 82 is provided outside of the optical modulator integrated semiconductor laser 10C, a transmission line from the second end of the terminating resistive film 82 to a connection point between the wire W21 and the signal pad 15 is elongated. Accordingly, since mismatching in impedance increases, reflection of a modulation signal in the terminating resistive film 82 is likely to increase due to an increase in frequency bandwidth of the optical modulator integrated semiconductor laser 10C. On the other hand, in the transmission micro optical device 1 according to the present embodiment, the modulation electrode 13, the signal pad 15, and the terminating resistive film 17 are provided on the same substrate 101. Accordingly, it is possible to extremely decrease the distance of the conductive path between the modulation electrode 13 and the first end 17a of the terminating resistive film 17. As a result, it is possible to decrease electrical reflection of a modulation signal at the first end 17a of the terminating resistive film 17. Accordingly, it is possible to reduce a loss of the modulation signal due to reflection.

In the transmission micro optical device 1 according to the present embodiment, the wire W21 and the wire W22 are provided side by side with each other. Since the wire W21 inputs a positive phase signal and the wire W22 inputs a negative phase signal in which the phase is opposite to that of the positive phase signal, a virtual reference potential line appears between the wire W21 and the wire W22. Accordingly, since mismatching in input impedance of the modulation signal in the wire W21 is reduced, it is possible to further reduce a loss of the modulation signal due to reflection. With this configuration, a gap between the wires can be substantially doubled in comparison with a single-phase driving configuration, that is, a configuration in which a wire with a ground potential is disposed on one or both sides of a single wire for transmitting a modulation signal. Accordingly, it is possible to increase a margin of the wire gap and to reduce difficulty in manufacturing. In the single-phase driving configuration, when an amount of heat generated changes according to an applied voltage and particularly an interval between bits included in the modulation signal is close to a thermal response time constant, the change in the amount of generated heat causes a change in quenching characteristics. On the other hand, in a differential driving configuration described in the present embodiment, since an amount of heat generated is maintained almost constant, it is possible to curb a change in quenching characteristics.

As in the present embodiment, the distance L1 of the conductive path between the connection point between the wire W21 and the signal pad 15 and the first end 17a of the terminating resistive film 17 may be less than ¼ of the wavelength of the modulation signal. The distance L2 of the conductive path between the connection point between the wire W21 and the signal pad 15 and the modulation electrode 13 may be less than ¼ of the wavelength of the modulation signal. With the knowledge of the inventor, when the frequency of the input modulation signal is, for example, a high frequency equal to or higher than 100 GHz and the distances L1 and L2 are less than ¼ of the wavelength of the modulation signal, electrical reflection of the modulation signal at the first end 17a of the terminating resistive film 17 is less likely to increase. Accordingly, it is possible to effectively reduce the loss of the modulation signal due to reflection. In 100 Gbps communication, the value of ¼ of the wavelength of the modulation signal is, for example, 300 μm, and the distances L1 and L2 are, for example, equal to or less than 100 μm.

As in the present embodiment, when seen in the thickness direction of the substrate 101, the wire W21 may be disposed in parallel with the wire W22. In this case, it is possible to more effectively reduce mismatching in impedance of the modulation signal in the wire W21. Accordingly, it is possible to further reduce the loss of the modulation signal due to the mismatching in impedance.

As in the present embodiment, a difference between the length of the wire W21 and the length of the wire W22 may be less than ¼ of the wavelength of the modulation signal. In this case, it is possible to reduce a skew between a positive phase signal and a negative phase signal.

As described above, the terminating resistive film 17 may include a material of at least one included in a group constituting of nickel chromium, titanium tungsten, tantalum nitride, and platinum. Accordingly, adhesiveness between the terminating resistive film 17 and the passivation film 102 is improved. It is possible to realize a desired resistance value.

As in the present embodiment, the laser unit 11 that outputs laser light may be provided on the substrate 101. Accordingly, it is possible to monolithically form the laser unit 11 and the optical modulation unit 12 on the same substrate 101, and to decrease the size of the transmission micro optical device 1.

### First Modified Example

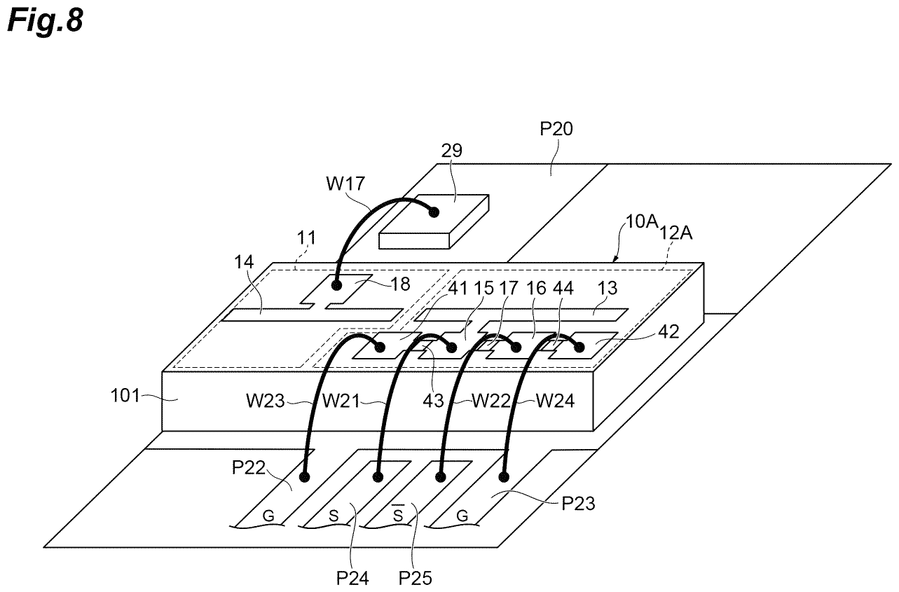

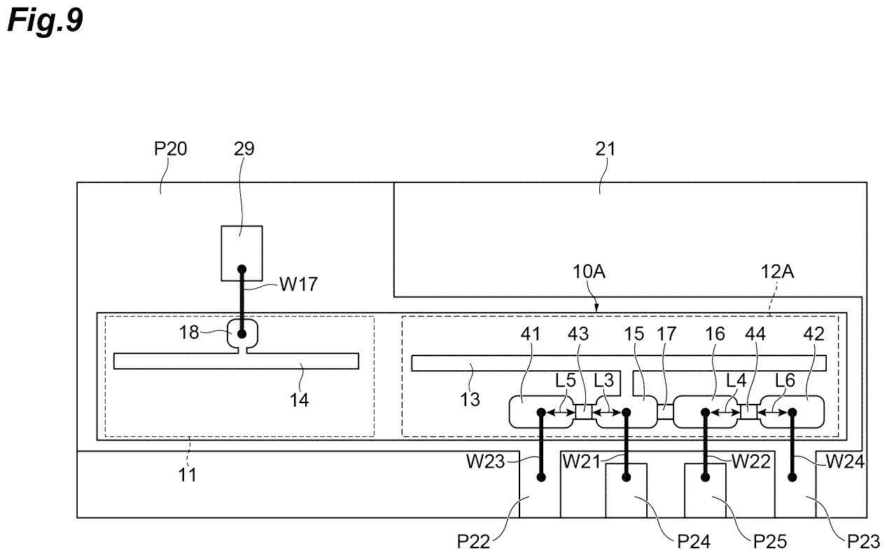

FIG. 8 is a perspective view illustrating enlargement of a part of a transmission micro optical device according to a first modified example. FIG. 9 is a plan view illustrating enlargement of a part of the transmission micro optical device according to the first modified example. The transmission micro optical device according to the present modified example is different from the transmission micro optical device 1 according to the first embodiment in the following points, and they are the same in the other points. The transmission micro optical device according to the present modified example includes an optical modulator integrated semiconductor laser 10A instead of the optical modulator integrated semiconductor laser 10 according to the first embodiment. The optical modulator integrated semiconductor laser 10A includes an optical modulation unit 12A instead of the optical modulation unit 12 according to the first embodiment. The other constituents of the optical modulator integrated semiconductor laser 10A are the same as those of the optical modulator integrated semiconductor laser 10.

The optical modulator integrated semiconductor laser 10A further includes a terminating resistive film 43 (a second terminating resistor) and a terminating resistive film 44 (a third terminating resistor) in addition to the terminating resistive film 17. The optical modulation unit 12A further includes a reference potential pad 41 (a third signal pad) and a reference potential pad 42 (a fourth signal pad) in addition to the signal pads 15 and 16. The optical modulation unit 12A further includes a wire W23 (a third wire) and a wire W24 (a fourth wire) in addition to the wires W21 and W22.

The reference potential pad 41 is provided in an area opposite to the signal pad 16 with respect to the signal pad 15 on the substrate 101. The reference potential pad 42 is provided in an area opposite to the signal pad 15 with respect to the signal pad 16 on the substrate 101. That is, the reference potential pad 41, the signal pad 15, the signal pad 16, and the reference potential pad 42 are sequentially arranged in the extending direction of the modulation electrode 13. The reference potential pad 41 and the reference potential pad 42 have a film shape and have a substantially rectangular shape in a plan view. The material of the reference potential pad 41 and the reference potential pad 42 are metal and are, for example, gold (Au). The thickness of the reference potential pad 41 and the reference potential pad 42 are, for example, equal to or greater than 3 μm and equal to or less than 10 μm.

The first end of the wire W23 is connected to the reference potential pad 41, and the second end of the wire W23 is connected to the ground potential line P22. The first end of the wire W24 is connected to the reference potential pad 42, and the second end of the wire W24 is connected to the ground potential line P23. Accordingly, the wire W23 and the wire W24 are set to the reference potential. The wire W23 and the wire W24 are provided side by side with the wire W21 and the wire W22 at positions at which the wire W21 and the wire W22 are interposed. That is, the wire W23, the wire W21, the wire W22, the wire W24 are sequentially arranged in the extending direction of the modulation electrode 13. When seen in the thickness direction of the substrate 101, the wire W23 and the wire W24 may be parallel with the wire W21 and the wire W22. The wire W23 and the wire W24 are, for example, bonding wires formed of Au. A diameter of a cross-section of the wire W23 and the wire W24 is, for example, 25 μm. The gap between the wire W21 and the wire W23 and the gap between the wire W22 and the wire W24 are, for example, several tens of μm.

The terminating resistive film 43 is provided between the signal pad 15 and the reference potential pad 41. The first end of the terminating resistive film 43 is connected to the signal pad 15. The second end of the terminating resistive film 43 is connected to the reference potential pad 41. The terminating resistive film 44 is provided between the signal pad 16 and the reference potential pad 42. The first end of the terminating resistive film 44 is connected to the signal pad 16. The second end of the terminating resistive film 44 is connected to the reference potential pad 42. The terminating resistive films 43 and 44 reduce reflection of a modulation signal. The terminating resistive films 43 and 44 have a rectangular shape. The material of the terminating resistive films 43 and 44 is, for example, a metal such as nickel chromium, titanium tungsten, tantalum nitride, or platinum. The thickness range and the formation method of the terminating resistive films 43 and 44 are the same as the terminating resistive film 17.

Here, the distance L3 is a distance of a conductive path (an electrical length) between the connection point between the wire W21 and the signal pad 15 and the first end of the terminating resistive film 43. The distance L4 is a distance of a conductive path (an electrical length) between the connection point between the wire W22 and the signal pad 16 and the first end of the terminating resistive film 44. The distance L5 is a distance of a conductive path (an electrical length) between a connection point between the wire W23 and the reference potential pad 41 and the second end of the terminating resistive film 43. The distance L6 is a distance of a conductive path (an electrical length) between a connection point between the wire W24 and the reference potential pad 42 and the second end of the terminating resistive film 44. These distances L3, L4, L5, and L6 are, for example, less than ¼, less than ⅛, less than 1/10, or less than 1/12 of the wavelength of the modulation signal. The distances L3, L4, L5, and L6 are, for example, equal to or greater than 1/1000 of the wavelength of the modulation signal.

For example, when differential impedance is 100Ω, the terminating resistive film 17 has only to have impedance of 200Ω, and the terminating resistive film 43 and the terminating resistive film 44 have only to have 100Ω. The gaps among the wire W23, the wire W21, the wire W22, and the wire W24 can be adjusted such that the differential impedance becomes closer to 100Ω.

In the optical modulator integrated semiconductor laser 10A according to the present modified example, the wire W23 and the wire W24 are set to the reference potential. Accordingly, a positive phase signal and a negative phase signal passing through the wire W21 and the wire W22 which are disposed between the wire W23 and the wire W24 are interposed between the ground potential. Accordingly, since mismatching in input impedance is further reduced, it is possible to further reduce a loss of a modulation signal.

The reference potential pad 41, the reference potential pad 42, the terminating resistive film 43, and the terminating resistive film 44 are provided on the same substrate 101 as provided with the signal pad 15 and the signal pad 16. Accordingly, the distance of the conductive path between the signal pad 15 and the first end of the terminating resistive film 43, the distance of the conductive path between the reference potential pad 41 and the second end of the terminating resistive film 43, the distance of the conductive path between the signal pad 16 and the first end of the terminating resistive film 44, and the distance of the conductive path between the reference potential pad 42 and the second end of the terminating resistive film 44 can be extremely decreased. Accordingly, it is possible to reduce reflection of a modulation signal in the terminating resistive film 43 and the terminating resistive film 44. As a result, it is possible to further reduce a loss of the modulation signal due to reflection.

As in the present modified example, the distances L3, L4, L5, and L6 may be less than ¼ of the wavelength of the modulation signal. Accordingly, it is possible to decrease reflection of the modulation signal in the terminating resistive film 43 and the terminating resistive film 44. Accordingly, it is possible to further reduce a loss of the modulation signal due to reflection. Second modified example

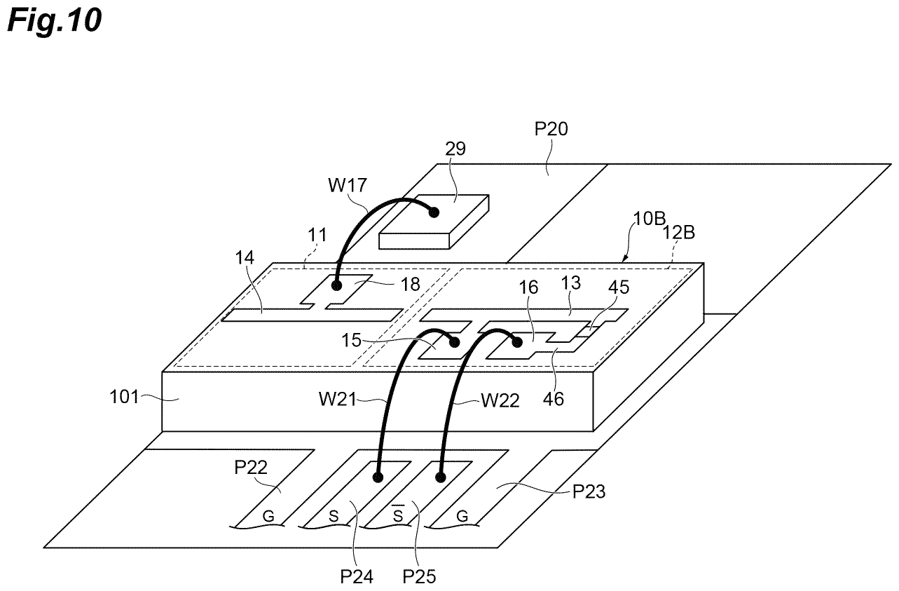

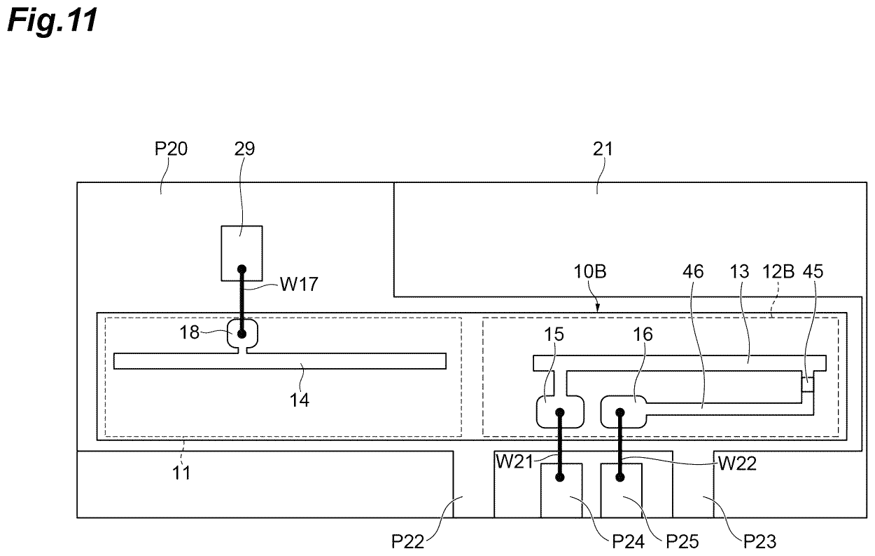

FIG. 10 is a perspective view illustrating enlargement of a part of a transmission micro optical device according to a second modified example. FIG. 11 is a plan view illustrating enlargement of a part of the transmission micro optical device according to the second modified example. The transmission micro optical device according to the present modified example is different from the transmission micro optical device 1 according to the first embodiment in the following points, and they are the same in the other points. The transmission micro optical device according to the present modified example includes an optical modulator integrated semiconductor laser 10B instead of the optical modulator integrated semiconductor laser 10 according to the first embodiment. The optical modulator integrated semiconductor laser 10B includes an optical modulation unit 12B instead of the optical modulation unit 12 according to the first embodiment. The other constituents of the optical modulator integrated semiconductor laser 10B are the same as those of the optical modulator integrated semiconductor laser 10.

The optical modulation unit 12B includes a terminating resistive film 45 (a first terminating resistor) provided on the substrate 101 instead of the terminating resistive film 17 according to the first embodiment. The optical modulation unit 12B includes a line 46 provided on the substrate 101. The line 46 is disposed on a side opposite to the signal pad 15 with respect to the signal pad 16. The line 46 includes a part extending along the modulation electrode 13. For example, the part of the line 46 is parallel with the modulation electrode 13. A first end of the terminating resistive film 45 is connected to the modulation electrode 13. A second end of the terminating resistive film 45 is connected to the signal pad 16 via the line 46. In other words, the line 46 connects the signal pad 16 to the terminating resistive film 45. The material, the thickness, and the formation method of the terminating resistive film 45 are the same as the terminating resistive film 17 according to the first embodiment.

The signal pad 15 and the signal pad 16 according to the present modified example are disposed in an area closer to the laser unit 11 in the optical modulation unit 12B. On the other hand, the terminating resistive film 45 is disposed in an area closer to the light emitting end in the optical modulation unit 12B. The first end of the terminating resistive film 45 is connected to a part of the modulation electrode 13 closer to the light emitting end of the optical modulation unit 12B.

In the present modified example, similarly to the first embodiment, the wire W21 and the wire W22 are provided side by side with each other. Since the wire W21 inputs a positive phase signal and the wire W22 inputs a negative phase signal in which the phase is opposite to that of the positive phase signal, a virtual reference potential line appears between the wire W21 and the wire W22. Accordingly, it is possible to reduce mismatching in input impedance of the modulation signal in the wire W21. The modulation electrode 13, the signal pad 16, and the terminating resistive film 45 are provided on the same substrate 101. Accordingly, it is possible to extremely decrease a distance of a conductive path between the modulation electrode 13 and the first end of the terminating resistive film 45. As a result, it is possible to reduce electrical reflection of the modulation signal at the first end of the terminating resistive film 45. Accordingly, it is possible to reduce a loss of the modulation signal due to reflection.

When seen in the thickness direction of the substrate 101, the wire W21 may be disposed in parallel with the wire W22. In this case, it is possible to more effectively reduce mismatching in impedance of the modulation signal in the wire W21.

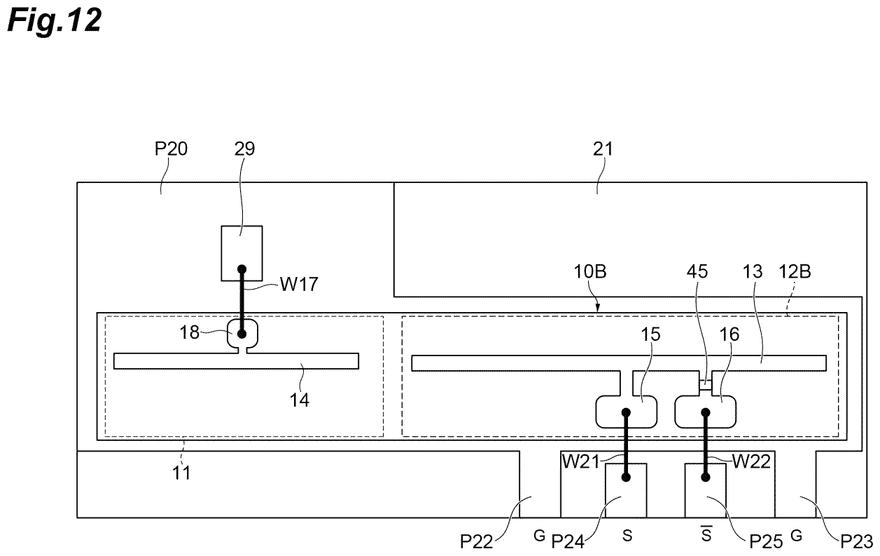

As in the present modified example, the optical modulator integrated semiconductor laser 10B may include the line 46 provided on the substrate 101 and connecting the signal pad 16 to the terminating resistive film 45. The line 46 may include a part extending along the modulation electrode 13. In this way, since the part of the line 46 in which a negative phase signal propagates extends in the modulation electrode 13, it is possible to reduce reflection of a negative phase signal in the terminating resistive film 45. Accordingly, it is possible to further reduce a loss of the modulation signal due to reflection. As illustrated in FIG. 12, the line 46 may be omitted, and the terminating resistive film 45 may be disposed between the signal pad 16 and the modulation electrode 13.

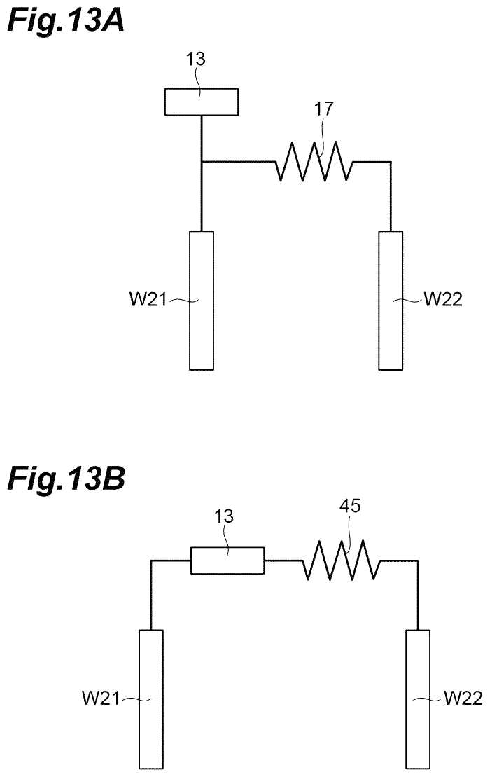

The first end of the terminating resistive film 17 in the first embodiment is connected to the signal pad 15, and the first end of the terminating resistive film 45 in the present modified example is connected to the modulation electrode 13. FIG. 13A is a circuit diagram illustrating simplification of a circuit according to the first embodiment. FIG. 13B is a circuit diagram illustrating simplification of a circuit according to the present modified example. When these circuit diagrams are compared, the modulation electrode 13 is present at positions branching from the wire W21 and the wire W22 (which include the terminating resistive film 45) which are signal lines in FIG. 13A, which constitutes a stub. This stub looks like capacitance or inductance according to the frequency. On the other hand, in FIG. 13B, the modulation electrode 13 is present between the wire W21 and the wire W22 (which include the terminating resistive film 45) which are signal lines. Accordingly, in comparison with FIG. 13A, it is possible to expect an advantageous effect of reducing an influence because of the stub looking like capacitance or inductance according to the frequency.

The optical modulator integrated laser device, the optical device, and the optical modulator according to the present disclosure are not limited to the aforementioned embodiment and the modified examples and can be modified in various forms. In the aforementioned embodiment, the wire W21 and the wire W22 are parallel with each other. The wire W21 and the wire W22 may be oblique with respect to each other. In this case, by arranging the wire W21 and the wire W22 side by side, it is possible to achieve the aforementioned advantageous effects.

In the aforementioned embodiment, the ground potential lines P22 and P23 of the transmission line 30 are provided on the substrate 21 side by side with the signal lines P24 and P25. The form of the transmission line is not limited thereto. For example, even when the transmission line is formed as a so-called micro strip line in which the ground potential lines are provided on the rear surface of the substrate 21, it is possible to achieve the aforementioned advantageous effects.

In the aforementioned description, resistive films are exemplified as examples of the first terminating resistor, the second terminating resistor, and the third terminating resistor. These terminating resistors are not limited to a resistive film, but may be another resistor.

What is claimed is:

1. An optical modulator integrated laser device comprising:
a substrate;
a laser unit provided on the substrate and configured to output laser light;
an optical modulation unit provided on the substrate, including a modulation electrode supplied with one of modulation signals, and configured to modulate the laser light;
a first signal pad provided on the substrate, configured to receive an input of the one of the modulation signals as a positive phase signal of a differential signal, and connected to the modulation electrode;
a second signal pad provided on the substrate side by side with the first signal pad and configured to receive an input of another of the modulation signals as a negative phase signal of the differential signal; and
a first terminating resistor provided on the substrate and including a first end connected to the first signal pad and a second end connected to the second signal pad.

2. The optical modulator integrated laser device according to claim 1, wherein a distance of a conductive path between a connection point of the first signal pad to which a first wire for inputting the one of the modulation signals is connected and the first end of the first terminating resistor is less than 1/4 of a wavelength of the modulation signals.

3. The optical modulator integrated laser device according to claim 2, wherein a distance of a conductive path between the connection point and the modulation electrode is less than 1/4 of the wavelength of the modulation signals.

4. The optical modulator integrated laser device according to claim 1, further comprising:
a third signal pad provided on the substrate on a side opposite to the second signal pad with respect to the first signal pad;
a fourth signal pad provided on the substrate on a side opposite to the first signal pad with respect to the second signal pad;
a second terminating resistor provided on the substrate and including a first end connected to the first signal pad and a second end connected to the third signal pad; and
a third terminating resistor provided on the substrate and including a first end connected to the second signal pad and a second end connected to the fourth signal pad.

5. The optical modulator integrated laser device according to claim 4, wherein a distance of a conductive path between a connection point of the first signal pad to which a first wire for inputting the one of the modulation signals is connected and the first end of the second terminating resistor is less than ¼ of a wavelength of the modulation signals.

6. The optical modulator integrated laser device according to claim 4, wherein a distance of a conductive path between a connection point of the second signal pad to which a second wire for inputting the another of the modulation signals is connected and the first end of the third terminating resistor is less than ¼ of a wavelength of the modulation signals.

7. The optical modulator integrated laser device according to claim 4, wherein a distance of a conductive path between a connection point of the third signal pad to which a third wire with a ground potential is connected and the second end of the second terminating resistor is less than ¼ of a wavelength of the modulation signals.

8. The optical modulator integrated laser device according to claim 4, wherein a distance of a conductive path between a connection point of the fourth signal pad to which a fourth wire with a ground potential is connected and the second end of the third terminating resistor is less than ¼ of a wavelength of the modulation signals.

9. An optical modulator integrated laser device comprising:
a substrate;
a laser unit provided on the substrate and configured to output laser light;
an optical modulation unit provided on the substrate, including a modulation electrode supplied with one of modulation signals, and configured to modulate the laser light;
a first signal pad provided on the substrate, configured to receive an input of the one of the modulation signals as a positive phase signal of a differential signal, and connected to the modulation electrode;
a second signal pad provided on the substrate side by side with the first signal pad and configured to receive an input of another of the modulation signals as a negative phase signal of the differential signal; and
a first terminating resistor provided on the substrate and including a first end connected to the modulation electrode and a second end connected to the second signal pad.

10. The optical modulator integrated laser device according to claim 9, further comprising a line connecting the second end of the first terminating resistor to the second signal pad,
wherein the line is provided on a side opposite to the first signal pad with respect to the second signal pad and extends along the modulation electrode.

11. An optical device comprising:
the optical modulator integrated laser device according to claim 1;
a carrier in which a first transmission line and a second transmission line are provided on a top surface and in which the optical modulator integrated laser device is mounted;
a first wire connecting the first signal pad to the first transmission line; and
a second wire connecting the second signal pad to the second transmission line.

12. The optical device according to claim 11, wherein a distance of a conductive path between a connection point of the first signal pad to which the first wire for inputting the one of the modulation signals is connected and the first end of the first terminating resistor is less than ¼ of a wavelength of the modulation signals.

13. The optical device according to claim 12, wherein a distance of a conductive path between the connection point and the modulation electrode is less than ¼ of the wavelength of the modulation signals.

14. An optical modulator comprising:
a substrate;
an optical modulation unit provided on the substrate, including a modulation electrode supplied with one of modulation signals, and configured to modulate laser light;
a first signal pad provided on the substrate, configured to receive an input of the one of the modulation signals as a positive phase signal of a differential signal, and connected to the modulation electrode;
a second signal pad provided on the substrate side by side with the first signal pad and configured to receive an input of another of the modulation signals as a negative phase signal of the differential signal; and
a first terminating resistor provided on the substrate and including a first end connected to the first signal pad and a second end connected to the second signal pad.

15. The optical modulator according to claim 14, wherein a distance of a conductive path between a connection point of the first signal pad to which a first wire for inputting the one of the modulation signals is connected and the first end of the first terminating resistor is less than ¼ of a wavelength of the modulation signals.

16. The optical modulator according to claim 15, wherein a distance of a conductive path between the connection point and the modulation electrode is less than ¼ of the wavelength of the modulation signals.

17. The optical modulator according to claim 14, further comprising a laser unit provided on the substrate and configured to output the laser light.
